(19) United States
(12) Patent Application Publication
(10) Pub. No.: US 2001/0036063 A1
(43) Pub. Date: Nov. 1, 2001

(54) Electronic part module mounted on

(75) Inventors: Kunio Nagaya, Ibi-gun (JP); Hiroaki Hayashi, Ibi-gun (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: IBIDEN CO., LTD., Ogaki-shi (JP)

(21) Appl. No.: 09/796,469

(22) Filed: Mar. 2, 2001

Related U.S. Application Data
(63) Continuation of application No. PCT/JP99/04554, filed on Aug. 23, 1999.

(30) Foreign Application Priority Data
Sep. 2, 1998 (JP) 10-248586
Oct. 29, 1998 (JP) 10-309116
Oct. 29, 1998 (JP) 10-309117
Nov. 6, 1998 (JP) 10-316000
Dec. 11, 1998 (JP) 10-352794

(51) Int. Cl. H05K 7/00

(52) U.S. Cl. 361/729

(57) ABSTRACT

An electronic part module which is configured to electrically connect an electronic component to a motherboard via a socket, including a conversion board and a sub board. The conversion board is configured to convert a signal from the electronic component and has a plurality of pins projected from the conversion board. The plurality of pins are configured to contact the socket. The sub board is provided between the conversion board and the socket and has a plurality of holes each having a diameter same as or larger than that of each of the plurality of pins which pass through the plurality of holes, respectively.

### CROSS-REFERENCE TO RELATED APPLICATION

The present application claims priority under 35 U.S.C. §119 to Japanese Patent Application Nos. 10-248586, 10-309116, 10-309117, 10-316000 and 10-352794, filed Sep. 2, 1998, Oct. 29, 1998, Oct. 29, 1998, Nov. 6, 1998 and Dec. 11, 1998, respectively. Further, the present application claims priority under 35 U.S.C. §120 to International Application No. PCT/JP99/04554, filed Aug. 23, 1999, entitled “ELECTRONIC PART MODULE MOUNTED ON SOCKET.” The contents of these applications are incorporated herein by reference in their entirety.

### BACKGROUND OF THE INVENTION

1. Field of the Invention

The present invention relates to an electronic part module mounted on a motherboard over a socket. For example, this module is used as a semiconductor package conversion module that is used when a semiconductor package comprising a CPU (a central processing unit) mounted on a motherboard over a PGA use socket is upgraded.

2. Discussion of the Background

A semiconductor package comprising a function as a CPU is mounted on a motherboard in a personal computer over a socket. For the present, as such a semiconductor package, PGA (pin grid array) type that a lot of I/o pins are stood in one side surface occupies the mainstream.

When a user desires upgrading the user's personal computer to speedup of processing, the user mounts a more high-functional semiconductor package afresh after detaching an existing semiconductor package from a socket. On that occasion it is proposed as a preferable structure that a high-functional semiconductor package is mounted over a conversion module indirectly on a socket in a motherboard.

Here, FIG. 26 shows one example of a conversion module 61 proposed conventionally. This conversion module 61 comprises a socket board 62 and a conversion board 63 as the main element. Plural plated through hole are made in the conversion board 63, and an end of an outside connecting pin 64 is inserted into each backside opening of the hole. Still, the outside connecting pin 64 is inserted into or extracted from a PGA use socket 65 on a motherboard MB. On the other hand, the socket board 62 comprises plural I/O pin 66. These I/O pin 66s are projected in a backside of the socket board 62 in a point corresponding to the plural plated through hole on the conversion board 63. Each I/O pin 66 is inserted and soldered to each plated through hole, and then electrical conduction with the socket board 62 and the conversion board 63 is attempted. In addition, because the I/O pin 66 of the socket board 62 is a socket-shaped pin having an inserting hole in the upper end surface of own, an I/O pin 68 of a semiconductor package 67 is fitted there. And an exchange connection is done about a specific I/O pin by a signal of a specific I/O pin being passed through a signal conversion component H on the conversion board once, and being sent to the outside connecting pin.

And, a PGA socket 65 comprises a socket main body 69 formed of a fixed part and a moving part. In the under surface side of the fixed part being comprised the socket main body 69, plural pin 70 is projected. The moving part including plural pin insert and extract hole 71 in which the outside connecting pin 64 is insertable and extractable is deployed in the top surface side of the fixed part. The moving part slides against the fixed part by a convolution movement of an operation lever 72, which made a fulcrum with a step part 73. As a result, each pin insert and extract hole 71 is made stricture, each outside connecting pin 64 becomes rigidify without slipping out possibility from the PGA use socket 65.

At first, the first problem is that: in a conventional electronic part module, when the module is inserted into or extracted from the PGA use socket 65, a not desiring external force toward the outside connecting pin 64 is easy to be applied. And as a result that a pin curve occurs, a relative position relationship between pin 64s may have been changed. In a module of FIG. 26 in particular, a pin curve is easy to become in comparison with a normal module, because a clearance between a backside of the conversion board 63 and a top surface of the PGA use socket 65 is big. In addition, the conversion module 61 may tilt, because an end in the side being distant from the step part 73 falls down by means of weight (cf. alternate long and two short dashes line of FIG. 26).

The second problem is that: in a conventional electronic part module, it is necessary a pin inserting process is divided into twice for a reason of a structure where two kinds of pins should be inserted in and be soldered to a top and bottom opening of a plated through hole on a conversion board 3. Therefore, the module has a weak point to need for a lot of manufacturing processes on a occasion of its production.

The third problem is a problem that appears as a side effect of the first invention. That is, adding a new substrate of a sub board, and laying a signal line on the substrate produce a troublesome soldering work between substrates.

The fourth problem is the problem that appeared as a side effect of the third invention. That is, the problem is how realize easily and surely an electrical connection with a build-up layer on a conversion board and a socket board.

The fifth problem is a problem that still continues to exist in the conventional electronic part module, the first invention, the second invention, the third invention and the fourth invention. That is, the problem is a desire of reducing an element comprising an electronic part module more.

### SUMMARY OF THE INVENTION

According to one aspect of the invention, an electronic part module which is configured to electrically connect an electronic component to a motherboard via a socket, including a conversion board and a sub board. The conversion board is configured to convert a signal from the electronic component and has a plurality of pins projected from the conversion board. The plurality of pins are configured to contact the socket. The sub board is provided between the conversion board and the socket and has a plurality of holes each having a diameter same as or larger than that of each of the plurality of pins which pass through the plurality of holes, respectively.

According to another aspect of the invention, an electronic part module which is configured to electrically connect an electronic component to a motherboard via a socket, includes a socket board and a conversion board. The socket board has a plurality of socket pins to which terminals of the electronic component are configured to be detachably connected. The conversion board is configured to convert a signal from the electronic component and has a plurality of pin insertion holes. The socket pins pass through the pin insertion holes to contact the socket.

According to yet another aspect of the invention, an electronic part module which is configured to electrically connect an electronic component to a motherboard via a socket, includes a conversion board. The conversion board is configured to convert a signal from the electronic component and has a build-up layer formed on a surface of the conversion board. A signal line necessary to convert the signal from the electronic component is provided on the build-up layer.

According to further aspect of the invention, an electronic part module which is configured to electrically connect an electronic component to a motherboard via a socket, includes a conversion board. The conversion board is configured to convert a signal from the electronic component and having a plurality of socket pin structures to which terminals of the electronic component are configured to be detachably connected.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic side view showing a use form of an electronic part module that is an embodiment realizing the first invention;

FIG. 2 is a partly enlarged cross-sectional view of the use form;

FIG. 3 is a plane view of a PGA use socket used in the embodiment;

FIG. 4 is a side view of a PGA use socket used in the embodiment;

FIG. 5 is a schematic plan view of a sub board used in the embodiment;

FIG. 6 is a schematic side view showing a use form of an electronic part module of another embodiment realizing the first invention;

FIG. 7 is a schematic side view showing a use form of an electronic part module of an embodiment realizing the second invention;

FIG. 8 is a partly enlarged cross-sectional view of the use form;

FIG. 9 is a partly enlarged cross-sectional view to show a use form of an electronic part module of another embodiment realizing the second invention;

FIG. 10 is a partly enlarged cross-sectional view to show a use form of an electronic part module of more another embodiment realizing the second invention;

FIG. 11 is a partly enlarged cross-sectional view to show a use form of a conversion module of more and more another embodiment realizing the second invention;

FIG. 12 is a schematic side view showing a use form of an electronic part module of an embodiment realizing the third invention;

FIG. 13 is a partly enlarged cross-sectional view of the use form;

FIG. 14 is a schematic side view showing a use form of an electronic part module of an embodiment realizing the fourth invention;

FIG. 15 is a partly enlarged cross-sectional view of the use form;

FIGS. 16(a)-16(d) are feature enlarged cross-sectional views to explain a production procedure realizing the fourth invention;

FIGS. 17(a)-17(d) are feature enlarged cross-sectional views to explain another production procedure realizing the fourth invention;

FIG. 18 is a schematic side view showing a use form of an electronic part module of an embodiment realizing the fifth invention;

FIG. 19 is a partly enlarged cross-sectional view of the use form;

FIG. 20 is a schematic plan view showing a wiring substrate of the embodiment;

FIG. 21 is a schematic side view showing a use form of an electronic part module of another embodiment realizing the fifth invention;

FIG. 22 is a partly enlarged cross-sectional view of the use form;

FIG. 23 is a schematic side view showing a use form of an electronic part module of another embodiment realizing the fifth invention;

FIG. 25 is a schematic side view showing a use form of an electronic part module of more another embodiment realizing the fifth invention; and

FIG. 26 is a schematic side view showing a use form of a conventional electronic part module.

### DESCRIPTION OF THE PREFERRED EMBODIMENTS

The preferred embodiments will now be described with reference to the accompanying drawings, wherein like reference numerals designate corresponding or identical elements throughout the various drawings.

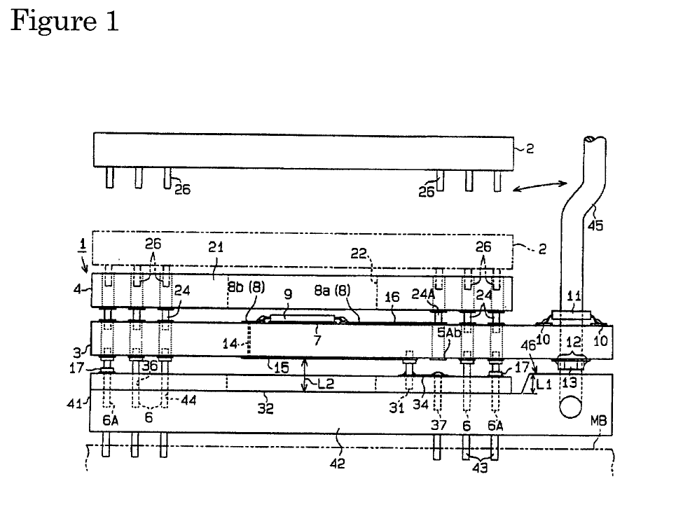

A signal conversion module 1 for a PGA of an embodiment is explained in detail based on FIGS. 1-5 as follows.

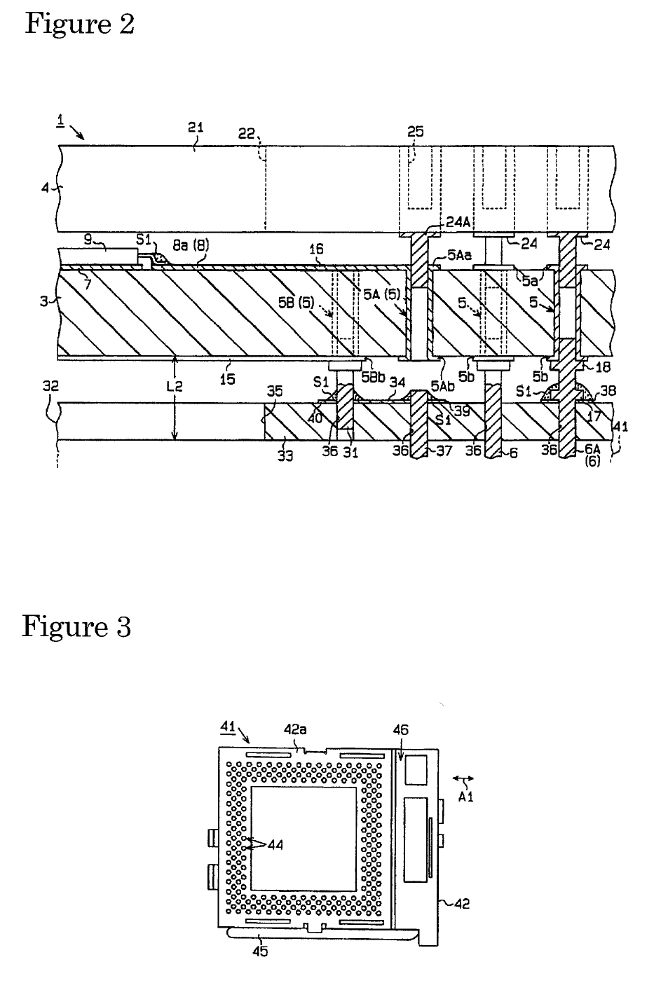

As shown in FIGS. 1 and 2, a conversion module 1 of this embodiment is a device that converts a signal of PGA 2 for a CPU, and mounts the CPU on a motherboard MB. The conversion module 1 comprises a plural substrate that is a conversion board 3, a socket board 4 and a sub board 32 as main components.

The conversion board 3 is a both sided rigid board (a wiring board comprising a conductor circuit on both main sides) with a rectangle shape observed in a plan. The conversion board 3 comprises a plated through hole group where a lot of plated through hole 5 (321 holes in the present embodiment) are disposed in the “□” shape observed in a plan. The plated through holes are placed in a lattice shape or a zigzag state by fixed pitch. In a backside open end of the plated through hole 5 aside from one plated through hole to be shown as 5A, an end of outside connecting pin 6, 6A is inserted (pushed-in). These pin 6, 6A may be joined to the hole 5 by soldering. Four outside connecting pin 6As being located in each corner portion comprises a brim part 17 named “stand off” in addition to a brim part 18 more. Outside connecting pin 6 occupying the majority comprises a brim part 18 only.

In an area of an about square shape observed in a plan surrounded by a plated through hole group in a surface side of a conversion board 3, one die pad 7 and multiple pad 8s surrounding the die pad 7 are formed. On the die pad 7, a QFP (a quad flat package) 9 for a signal conversion as a signal conversion element is mounted. Each lead of the QFP 9 is joined to each pad 8 with solder S1 that is an electro conductivity material. In addition, in this embodiment, one of the multiple pad 8s is assigned as an input side pad 8a for an exchange connection, and one of the other multiple pad 8s is assigned as an output side pad 8b for the exchange connection.

This input side pad 8a is connected electrically with a surface side land 5Aa of above described plated through hole SA over a conductive pattern 16 in a conversion board 3.

And, in an area of the about square shape observed in a plan, a plated through hole 5B that is different from above described plated through hole 5, 5A is formed. To a backside opening of this plated through hole 5B, an end of a second pin 31 is inserted and soldered. This pin 31 is formed a little shorter than an outside connecting pin 6, 6A.

And, in the area of the about square shape observed in a plan, a mini-via hole 14 is made more. The mini-via hole 14 is a hole that has a smaller diameter (dozens of μ m φ) than a diameter of a normal plated through hole formed to be inserted a pin in and to connect front and back sides, and formed only to connect front and back sides. To an upper end of the mini-via hole 14, above described output side pad 8b is connected electrically. A bottom end of the mini-via hole 14 and a backside land 5Bb of a plated through hole SB are connected electrically by a conductive pattern 15 on a conversion board 3.

In an area not surrounded by a through hole group in a surface side of a conversion board 3, a pad 10 for an electronic component connection is formed. On the pad 10, a DIP (dual-in-line package) 11 is mounted. In a backside of the conversion board 3, an electronic component connecting pad 12 is formed, and a chip resistor 13 is mounted there. These electronic component 11, 13 are joined to each pad 10, 12 with solder S1, too.

In fact, in a backside of a conversion board 3, some other conductive patterns not illustrated are formed. The conductive pattern electrically connects a land 5b of a plated through hole 5a and a pad 12 for an electronic component 13. In a surface side of the conversion board 3 either, some similar conductive patterns not illustrated are formed. The conductive pattern electrically connects a land 5a of a plated through hole 5, a pad 8 of a QFP 9 and a pad 10 for an electronic component 11 mutually.

Next, a constitution of a socket board 4 is described. As shown in FIGS. 1 and 2, an insulation substrate 21 being comprised a socket board 4 has a square shape and a frame shape observed in a plan, and an external size of it is generally equal to a size of a PGA 2 that is an object to be mounted. The insulation substrate 21 comprises a center-opening 22 of a square shape observed in a plan. A reason why such a center opening 22 is made for is to ensure an accommodation space of a QFP 9 and to radiate heat of the QFP 9 efficiently.

In a circumference of a center opening 22, a pin inserted hole 23 is formed a lot. In the each pin-inserted hole 23, a socket-shaped I/O pin 24, 24A are inserted respectively. A number of the socket-shaped I/O pin 24, 24A is 321 in the present embodiment. A bottom end of the I/O pin 24, 24A is projected from a lower part side of an insulation substrate 21, and inserted into and soldered to a plated through hole 5, 5A on a conversion board. In the each socket-shaped I/O pin 24, 24A, an inserted hole 25 being prolonged in consonance with its axis direction is formed. Into or from this inserted hole 25, an I/O pin 26 of a PGA 2 can be inserted and extracted. That is, the socket board 4 has a structure where the PGA 2 can be inserted into and extracted from in a top surface side.

A conversion module 1 of the present embodiment comprises a sub board 32 shown in FIGS. 1, 2 and 5 as a component more in addition to a conversion board 3 and a socket board 4. In the following, a structure of the sub board 32 is described.

A sub board 32 placed in a state of being separated from a conversion board 3 with a predetermined interval in a backside of a conversion board 3. An insulation substrate 33 that is a constitution member of the sub board 32 is a plane regard rectangle and made from a rigid material, and comprises a pentagon-shaped center opening 35. An external form shape and a dimension of this center opening 35 are generally equal to a shape and a dimension of a tall electronic component (not illustrated) such as a volume to be mounted on a backside of the above described conversion board. In a circumference of the center opening 35, a pin penetrating hole 36 is formed a lot. Into the pin penetrating hole 36, an outside connecting pin 6, 6A on the above described conversion board is penetrated. In other words, a bottom end of the each outside connecting pin 6, 6A protrudes from an under surface side of the insulation substrate 33. Still, a diameter of the pin penetrating hole 36 is the same or a little larger than a diameter of the outside connecting pin 6, 6A.

In a plural point in a top surface side of an insulation substrate 33 (in FIG. 5, amounted to 6 places), a land-shaped pattern 38, 39, 40 are formed. The land-shaped pattern 38 is formed on a top face side open end of the pin penetrating hole 36 that the outside connecting pin 6A is penetrated into. When four outside connecting pin 6As in a corner portion are inserted in the pin penetrating hole 36, a bottom end of a brim part 17 contacts and is supported by a top surface of a land-shaped pattern 38. And in this state, the brim part 17 of the outside connecting pin 6A and the land-shaped pattern 38 are soldered.

As shown in FIG. 5, a land-shaped pattern 39 and 40 is comparatively approached mutually, and connected over a conductive pattern 34 electrically. As thus described, a sub board 32 of the present embodiment is so-called a one sided board comprising a conductive pattern 34 only in the upper surface of an insulation substrate 33 (a wiring board comprising a conductor circuit on only one surface). Still, in FIG. 5, in a convenience of a drawings making, a number of a pin penetrating hole 36 is described fewer than a fact.

A land-shaped pattern 39 is formed at an upper side opening of a pin penetrating hole 36 in a position corresponding to a plated through hole 5A on a conversion board (that is, a position corresponding to a specific I/O pin 24A where an exchange connection is necessary), and is soldered to an upper end of a first pin 37 being inserted in the pin penetrating hole 36.

A land-shaped pattern 40 is formed at an upper side opening of a pin penetrating hole 36 where a bottom end of a second pin 31 on a conversion board is inserted in, and is soldered to a bottom end of the second pin 31.

As shown in FIG. 2, a length of a distance from a backside of a conversion board 3 to a top face of a sub board 32 is generally determined by a distance between a brim part 17 and a brim part 18 basically. A value that added a depth of an insulation substrate 33 to this distance is generally equivalent to a length L2 of a distance between a backside of the conversion board 3 and a lower part of the sub board 32.

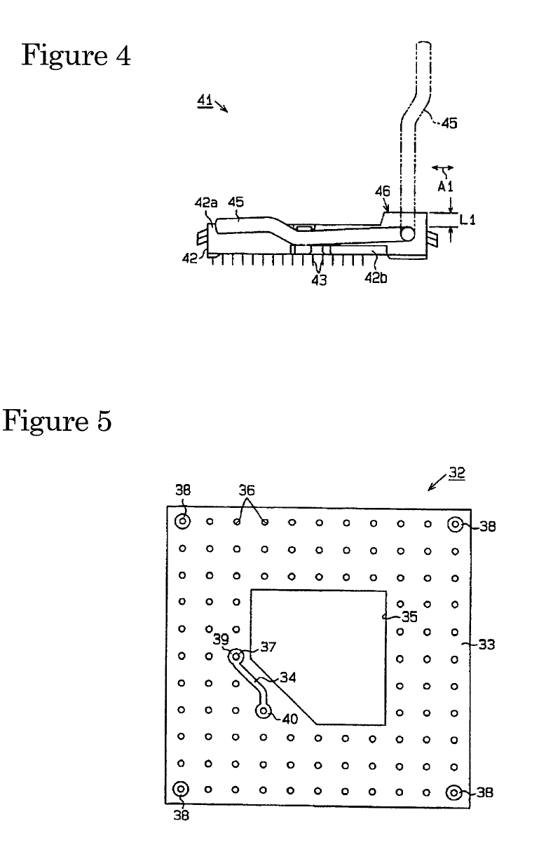

As a PGA socket 41, “Socket 5” or “Socket 7” (every, in the ZIF series) made by Thomas and Betz Company is used as shown in FIGS. 3 and 4. In particular a length L2 of a distance between a backside of a conversion board 3 and an under surface of a sub board 32 is set bigger than a height L1 of a step part 46.

The conversion module 1 as thus constituted moves as following, when it is mounted on a socket 41 for a PGA of a motherboard MB after being mounted a PGA2 on.

A signal of PGA2 flowing through a specific I/O pin 24A passes through a route of a land 5Aa of a plated through hole 5Aa→conductive pattern 16→an input side pad 8a, and is input into a QFP 9. The signal being converted by and being output from the QFP 9 passes through a route of a output side pad 8b→a mini-via hole 14→a conductive pattern 15→a land 5Bb of a plated through hole SB, and is led to a second pin 31. The signal being led to the second pin 31 passes more a route of a land-shaped pattern 40 a conductive pattern 34→a land-shaped pattern 39→the first pin 37→a pin 43 of a PGA use socket 41, and is supplied to a motherboard MB side. That is, the specific I/O pin 24A does not connect directly to an outside connecting pin 6 via a plated through hole 5A being corresponded to. And as a result that an exchange connection using a sub board 32 in this way is done, a signal is converted principally by the QFP 9, and then an original function of the PGA 2 becomes show enough.

Therefore, the following effects can be got according to the present embodiment.

(1) Every outside connecting pin 6, 6A is in a state of being penetrated into a pin penetrating hole 36 of which diameter is the same to or a little bigger than the pin diameter. So, even if an external force is applied to one outside connecting pin 6, 6A, which seems to bend the pin, the external force disperses in every pin 6, 6A by spreading on a sub board32. Because of this, a preferred conversion module 1 that a pin curve is hard to occur can be realized. Therefore, a relative position of the outside connecting pin 6, 6A is not changed, and an extraction and insertion of the pin 6, 6A does not cause a trouble.

(2) In the present embodiment, a socket 41 for PGA with a step part 46 is used, and an under surface of a sub board 32 is supported in a state of being abutted overall on a top surface of a PGA use socket 41 at a mounting a conversion module 1. Here, a length L2 of a distance between a backside of the conversion board 3 and an under surface of the sub board 32 is set bigger than a height L1 of the step part 46. Because of this, at this time, an end in a side far-off from the step part 46 must not fall down. Therefore, the conversion board 3 can stand being weighted with mounting a PGA 2, and the conversion module 1 is hard to become lean to. In addition, by these reason, as the conversion module 1 can be mounted on without stretching out from the socket 41 for PGA, it has an advantage of not obstructing an electronic component mounted on a motherboard MB.

(3) This conversion module 1 comprises four outside connecting pin 6As each having a brim part 17. The conversion module 1 can be hold in a position of a preferable length of a distance between a backside of a conversion board 3 and an under surface of a sub board 32 surely because these brim part 17s are supported by the top surface of the sub board 32. In this embodiment in particular, an outside connecting pin 6A is arranged in each corner portion, in plural points being set apart from each other in other words. As a result, a parallel relation with the conversion board 3 and the sub board 32, and a parallel relation with the conversion board 3 and a PGA use socket 41 are kept.

(4) A sub board 32 used in the present embodiment does not increase a cost of the whole, because it uses a one sided board comprising a simple structure. In addition, as the sub board 32 is made of an insulation substrate 33, it does not short-circuit between outside connecting pin 6s, 6As penetrated into each pin penetrating hole 36.

Still, the embodiment of the present invention may be changed as follows.

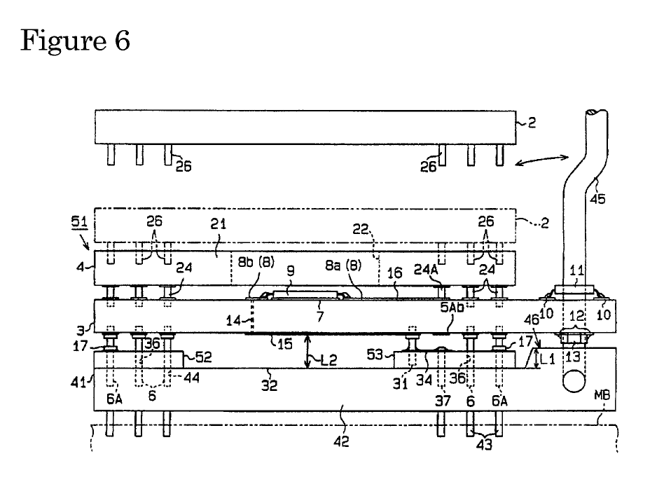

In the embodiment, only one substrate of a large area is used as a sub board 32. Without being limited to that, like a conversion module 51 shown in FIG. 6, two sub board 52, 53 that are comparatively small and multiple substrates (in this, two pieces) can be used. Even if the conversion module 51 has that constitution, a pin curve and a leaning at mounting a PGA use socket 41 can be avoided. Of course an exchange connection on a specific I/O pin 24A can come true.

The present invention can be realized not only as a signal conversion module 1 such as the embodiment, but also as an electronic part module aside from it. For example, a pin curves of a PGA can be avoided when the present invention is realized as a PGA comprising a sub board.

The present invention may be applied to as a socket for a PGA that does not have a step part 46 in particular.

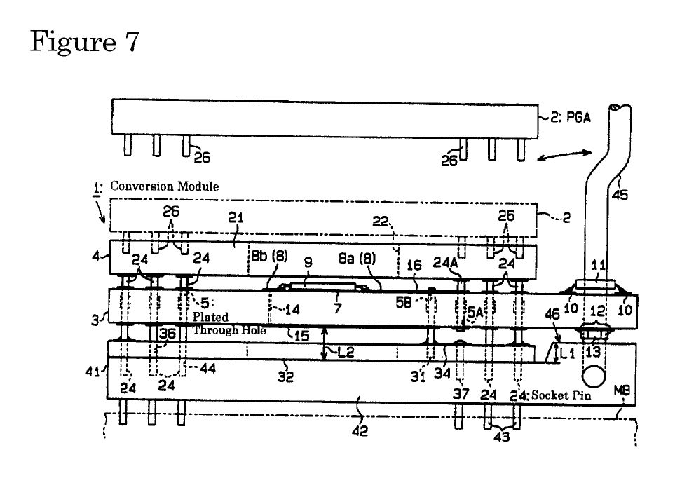

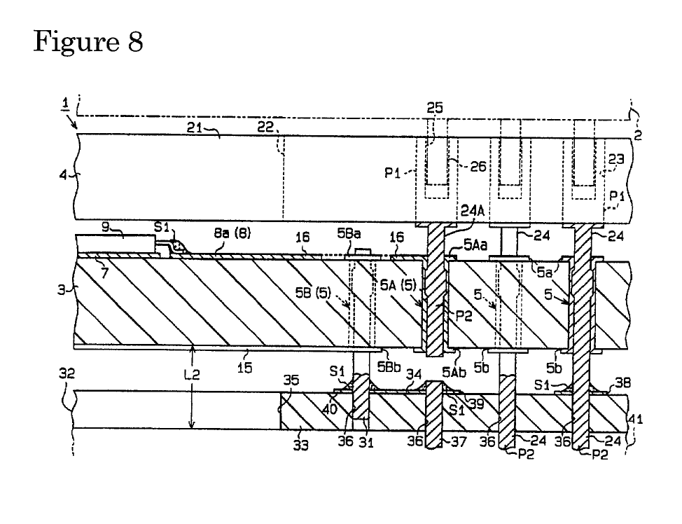

A signal conversion module 1 for a PGA of one embodiment is explained to the details based on FIGS. 7 and 8.

As shown in FIG. 7, this conversion module 1 of this embodiment converts a signal of a PGA 2 for a CPU, and mounts it on a motherboard MB.

Because the conversion module 1 has a conversion board 3, a socket board 4 and a sub board 32 as main constitutions, same as the above described embodiment of the first invention, only a particularly different point is described below.

As shown in FIGS. 7 and 8, in each plated through hole 5, 5A in a conversion board 3, a leg P 2 of each socket pin 24, 24A on a socket board 4 is penetrated. In the present embodiment, the leg P 2 is pushed in and fixed to (in other words, is press-fitted in) the plated through hole 5, SA without being soldered to.

A leg P 2 of a specific socket pin 24A needing an exchange connection is formed somewhat shortish as compared to a socket pin 24 where the exchange connection is not needed for. Therefore, a tip of this socket pin 24A protrudes from an under surface side opening of a plated through hole SA slightly, and does not extend to a position of a sub board 32.

A leg P 2 of each socket pin 24 being formed longer reaches a position of a sub board 32, and is penetrated into a pin penetrating hole 36. A tip of the leg P 2 of each socket pin 24 protrudes from an under surface side of the sub board 32 with only a length share to be able to insert and extract in a pin insert and extract hole 44. A leg P 2 of a socket pin 24 being located in each corner portion is soldered to a corresponding land-shaped pattern 38.

In a plated through hole SB, an upper end of a second pin 31 is press-fitted without being soldered. A bottom end of the second pin 31 is inserted into a corresponding pin-penetrating hole 36, and is soldered to a land-shaped pattern 40. But this pin 31 does not protrude from an under surface side of a sub board 32.

And, in a pin penetrating hole 36 having a land-shaped pattern 39, a first pin 37 is penetrated. An upper end of the first pin 37 is soldered to the land-shaped pattern 39. A bottom end of the first pin 37 protrudes from an under surface side of a sub board 32 with only a length share to be able to insert and extract in a pin insert and extract hole 44. And a conductive pattern 34 connects electrically the second pin 31 and the first pin 37.

Next, one example of a method to produce this conversion module 1 is introduced.

At first, a conversion board 3, a socket board 4 and a sub board 32 are made beforehand. The conversion board 3 can be got by a pattern formation of a conventionally common awareness such as a subtractive process with a starting material of a copper-clad laminate that is a copper foil being attached onto both sides of an insulation substrate made from glass epoxy, for example. Then, in the insulation substrate, a plated through hole 5, 5A, 5B, a mini-via hole 14, a die pad 7, a pad 8, 8a, 8b and so on are formed. A socket board 4 can be got comparatively easily by using a commercial product as a starting material. That is, it can be made by cutting a predetermined length of a specific pin (a pin should become a socket pin 24A after) among the socket pin 24 of a commercial product. A sub board 32 can be made by a subtractive process with a starting material of a copper-clad laminate that is a copper foil being attached onto one side of an insulation substrate made from glass epoxy, for example.

In continuing the first soldering process, on a pad 12 in an under surface side of a conversion board 3, by means of a screen printing for example, cream solder is printed. And, an electronic component 13 is soldered to the pad 12 by means of a re-flow soldering in the state of the electronic component 13 being fixed temporary by being put on the pad 12.

In next the second soldering process, the conversion board 3 is reversed, and cream solder is printed on a conductor layer (each pad 8, 8a, 8b, 10) in a top surface side. In the present embodiment adopting a means of press-fitting, cream solder is not printed on a top surface side land 5a, 5Aa , 5Ba of a plated through hole 5, 5A, 5B. And each lead of a QFP 9 is put in each pad 8, 8a, 8b, and is fixed temporary, and then an electronic component 11 is put in a pad 10, and is fixed temporary. A re-flow is done in this state, and then the QFP 9 and the electronic component 11 are soldered to each conductor layer.

In continuing a pin inserting process, into each plated through hole 5, 5A of a conversion board 3, a leg P2 of a socket pin 24, 24A is press-fitted from a top surface side opening of the hole 5. And, into a plated through hole 5B, a second pin 31 is press-fitted. At this time, a projecting part formed at a predetermined point of a circumference plane of a press-fitted portion somewhat bites into a copper-plating layer in the plated through hole 5, 5A, 5B. As a result, an electrical conduction between the socket pin 24, 24A and a plated through hole 5, 5A, and between the second pin 31 and the plated through hole 5B are attempted without being soldered.

Next, into a pin penetrating hole 36 of a sub board 32, a leg P2 of a socket pin 24 and a tip of a second pin 31 are penetrated, and the first pin 37 is inserted. In this state, each pin 24, 37, 31 are soldered to each land-shaped pattern 38, 39, 40 respectively.

A conversion module 1 as thus constituted works as follows by being mounted on a socket 41 for a PGA of a motherboard MB after mounting a PGA2.

A signal of a PGA 2 flowing through a specific socket pin 24A passes through a route of a land 5Aa of a plated through hole 5A→a conductive pattern 16→an input side pad 8a, and is input to a QFP 9. After the signal is converted by the QFP, a converted signal passes through a route of an output side pad 8b→a mini-via hole 14→a conductive pattern 15→a land 5Bb of a plated through hole SB, and is led to a second pin 31. The converted signal led to the second pin 31 passes more through a route of a land-shaped pattern 40→a conductive pattern 34→a land-shaped pattern 39→a first pin 37→a pin 43 of a PGA use socket 41, and is supplied to a motherboard MB side. That is, in a conversion module of the present embodiment, an original function of a PGA 2 becomes show enough because a signal is converted by a QFP 9 principally as a result of a exchange connection used a sub board 32.

Therefore, the following effects can be got according to the present embodiment.

(1) In this conversion module 1, a leg P2 of a socket pin 24 is connected to and penetrates through a plated through hole 5 of a conversion board 3, and penetrates a pin penetrating hole 36 of a sub board 32, and a tip of the socket pin 24 protrudes from an under surface side of the sub board 32 with a length to be able to insert and extract in a pin insert and extract hole 44 of a PGA use socket 41 still in the lower part. Because a conversion module of the present embodiment is such a constitution, it is not need to insert and to solder two kinds of pins to an opening above and below a plated through hole 5, and then a pin inserting process is finished at once. Therefore, the conventional weak point that a lot of manufacturing processes are needed for the production is dissolved, and then the conversion module 1 can be produced simply and surely.

(2) In this conversion module 1, a socket pin 24, 24A are press-fitted into a plated through hole 5, 5A without being soldered. Therefore, it is not need to supply solder to a joint part of a socket pin 24, 24A and a plated through hole 5, 5A by means of printing beforehand for example. So, this conversion module 1 is easy to be produced.

(3) In this conversion module 1, a sub board 32 having a conductive pattern 34 is arranged in an under surface side of a conversion board 3. Therefore, a pin curve is hard to occur by a reason of a leg P2 of each socket pin 24 being fixed mutually by an insulation substrate 33. So, a relative position of the socket pin 24 does not collapse, and then inserting to or extracting from a pin insert and extract hole 44 of the socket pin 24 becomes easy.

In addition, the embodiment of the present invention may be changed as follows.

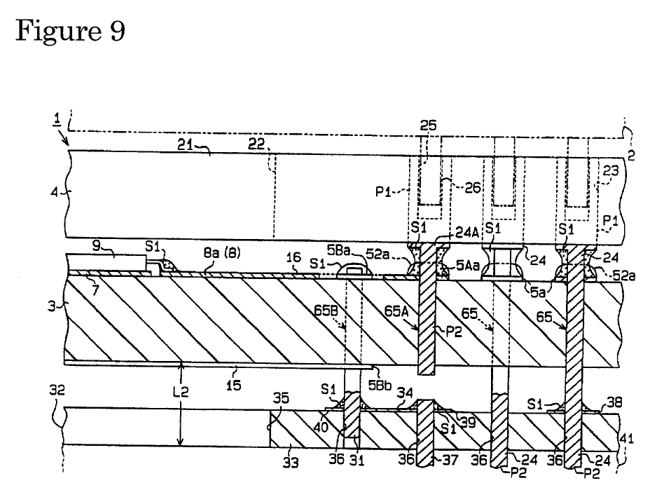

In a conversion module 61 shown in FIG. 9, instead of forming a plated through hole 5, 5A, SB in a conversion board 3, a simple pin inserted hole 65, 65A, 65B are formed. On an inner wall side of the pin inserted hole 65, 65A, 65b, a copper metal plating layer is not formed. At a top surface side opening of the pin inserted hole 65, 65A, 65B, a land-shaped pattern 5a, 5Aa , 5Ba is formed respectively. And a socket pin 24 is soldered to the land-shaped pattern 5a, a socket pin 24A is soldered to the land-shaped pattern 5Aa and a second pin 31 is soldered to the land-shaped pattern 5Ba. Therefore, according to this embodiment, the following effects can be got in addition to the above described effect (1) and (3) of the first embodiment.

(4) In the present embodiment, a re-flow is done in a state of a joining portion of socket pin 24, 24A and land 5a, 5Aa being supplied with a solder layer 52a (or 52b, 52c) of a proper amount beforehand. Therefore, without overs and shorts of a quantity of solder, both can be joined surely. In other words, a connection reliability of the socket pin 24, 24A and the land 5a, 5Aa can be improved. Therefore, a conversion module 51 with a pin soldering fixation structure can be produced surely.

(5) Because it is not necessary for this conversion module 61 to form a copper metal plating layer on an inner wall side of a through-hole, an inexpensive conversion board 3 can be used. Therefore, this conversion module 61 is suitable for preventing high cost accounting as a whole.

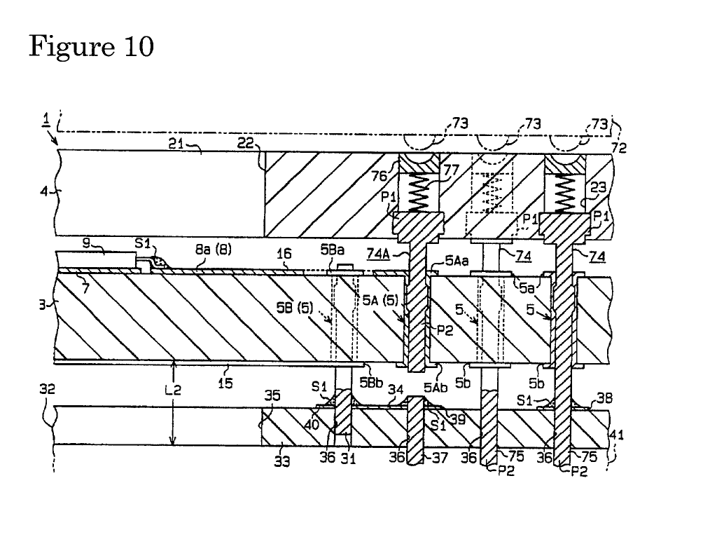

A conversion module 71 shown in FIG. 10 is formed to mount a BGA (Bump Grid Array) 72 that is a kind of a chip module. In an under surface of a BGA 72, a something like semicircular-shaped bump 73 as a terminal is projected a lot. This socket board 4 comprises lot of socket pin 74 for a BGA. The socket pin 74 for a BGA has a structure that coupled a half 76 with a spring 77 in a lower half 75. The lower half 75 consists of a head P1 and a leg P2 that diameter is smaller than that of a head P1, and the head P1 is held without slipping out possibility by a pin holding hole 23. The upper half 76 is accommodated in the pin holding hole 23 with a state of its sliding to the top and bottom direction is possible. In an upper end surface of the upper half 76, a semicircular-shaped recess is formed, and a bump 73 can be pushed to the recess. A code 74A are referred to a socket pin of which an exchange connection is necessary. A conversion module 71 of this structure can also be produced easily, besides it has superior connection reliability.

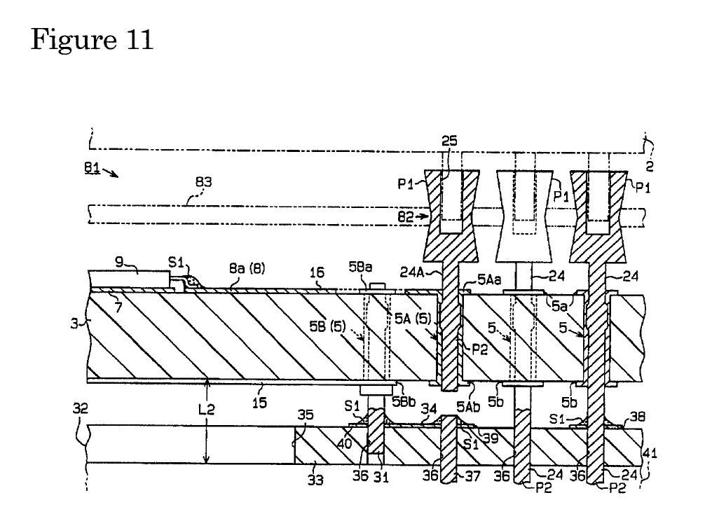

A conversion module 81 shown in FIG. 11 is different from the above-described embodiment in only a socket pin 24, 24A being mounted on without a socket board 4. The socket pin 24, 24A used here is so-called a jaw adding socket pin of which head P1 has almost a hand drum shape. At the time of a pin being supplied, a jaw part 82 of each socket pin 24, 24A is inserted and held in a holding hole of a film 83 made from a polyimide resin. Since this film 83 has flexibility, it can be easily removed after a pin inserting process if unnecessary. Of course if it is necessary, the film 83 may be used as it is.

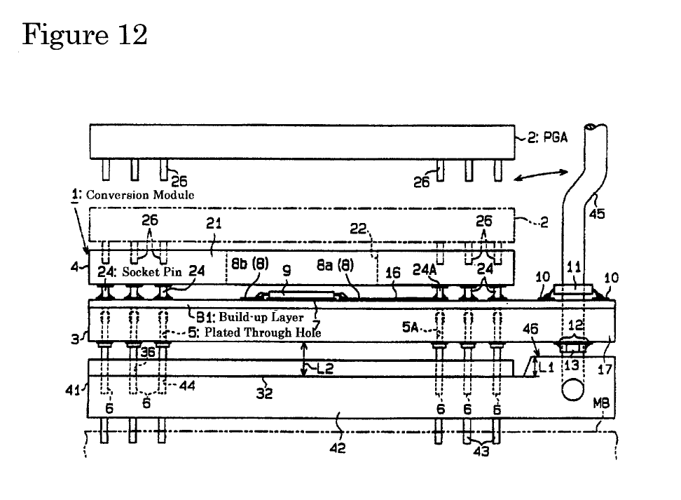

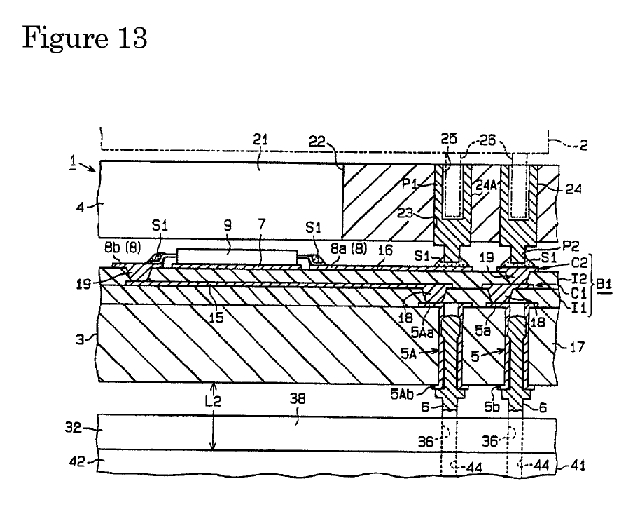

A PGA use conversion module 1 according to one embodiment of the present invention is explained with being based on FIGS. 12 and 13 as follows.

As shown in FIGS. 12 and 13, a conversion module 1 of this embodiment is a device that mounts a PGA 2 on a motherboard MB with converting a predetermined signal of the PGA 2 that is a kind of a chip module, as same as the first and second embodiments.

One example of a method to produce this conversion module 1 is introduced below.

At first, a conversion board 3 is made beforehand. The conversion board 3 can be got by a pattern formation of a conventionally common awareness such as a subtractive process with a starting material of a core substrate 17 that is a copper foil being attached onto both sides of an insulation substrate made from glass epoxy, for example. Then, in the core substrate 17, a plated through hole 5, 5A, a pad 12 are formed. Still, it is preferable for every land 5a, 5b of each plated through hole 5 to be formed into a same shape. In addition, in an area of a plated through hole group, it is preferable for a conductive pattern aside from the land 5a, 5b not to be formed. The reason is it can make a conversion board 3 with a universal core substrate 17 of high multiusability. A socket board 4 can be use a commercial product having a short socket pin 24.

In continuing a build-up layer forming process, a build-up layer B1 is formed in a top surface of a core substrate 17 being comprised a conversion board 3 by a build-up process.

At first, an additive process use adhesive of a photosensitive epoxy system is applied to a top surface of a core substrate 17 here. The additive process use adhesive of a photosensitive epoxy system is an adhesive having a resin filler that is comparatively easy to dissolve in an oxidizer, which is dispersed in a resin matrix that is comparatively difficult to dissolve in the oxidizer. Next, an insulating layer I1 having a hole for a via hole, of which inside diameter is dozens of μm degree is formed by means of the exposure/developing. And the insulating layer Ii is roughened with chromic acid as a roughening material (an oxidizer) by a chemical roughening preprocessing. And a catalyst addition, a forming of a permanent resist layer (an illustration abbreviation), a metal plating preprocess and an electro less copper pattern plating are done afterwards. A copper metal plating layer is deposited on a permanent resist layer non-forming portion and an inner wall side of a hole for a via hole by this, then a conductive pattern 15 and a via hole 18 are formed on the insulating layer I1. The via hole 18 formed in this way becomes so-called a filled via where a hole for a via hole is completely buried in by a copper metal plating layer.

Furthermore, about a top surface of the insulating layer I1 where a via hole 18 is formed, an application of an adhesive layer, an exposure, a developing, a roughening preprocess, a catalyst addition, a forming of a permanent resist layer, a plating preprocess and an electro less copper plating are done in accordance with a similar procedure to the above. As a result, a pad 7, 8, 8a, 8b, 10, a conductive pattern 16 and a via hole 19 are formed on the insulating layer I 2, and then a desired build-up layer B1 is completed.

In continuing the first soldering process, cream solder is printed on a pad 12 in an under surface side of a conversion board 3 by means of a screen printing for example. And an electronic component 13 is soldered to a pad 12 by doing a re-flow process in a state of an electronic component 13 being fixed temporary in the pad 12.

In continuing a pin inserting process (a pin press-fit process), a conversion board 3 is put on a workbench of a pin-driving device in a state of a side of a build-up layer B1 of the conversion board 3 being turned into beneath. On that occasion, it is preferable to dispose an elastic body such as a rubber sheet between a top surface of the bench and the build-up layer B1. And to each plated through hole 5, SA of the conversion board 3A, an end of an outside connecting pin 6 is press-fitted from an under surface side opening. At this time, a projecting part formed at a predetermined point of a circumference plane that is press-fitted somewhat bites into a copper-plating layer in the plated through hole 5, 5A As a result, an electrical conduction between the outside connecting pin 6 and the plated through hole 5, 5A is attempted without soldering.

In next the second soldering process, turn to a build-up layer B1 side above by reversing a conversion board 3, and cream solder is printed on a pad 8, 8a, 8b, 10 and both end parts of a conductive pattern 16 on the build-up layer B1. At this time, cream solder is printed on an upper end surface of each via hole 19 simultaneously.

And each lead of a QFP 9 is put on each pad 8, 8a, 8b, an electronic component 11 is put on a pad 10, a leg P2 of each socket pin 24 is put on an upper end surface of a corresponding via hole 19 and a leg P2 of a socket pin 24A is put on an upstream edge of a conductive pattern 16. A QFP 9, an electronic component 11 and a socket pin 24, 24A are soldered to each portion by doing a re-flow process in such a state of being fixed temporary. As a result that soldering of an upper end surface side of a core substrate 17 is done as above, a socket board 4 become to be mounted on a conversion board 3.

Next, an outside connecting pin 6 is penetrated into a pin-penetrating hole 36 of a sub board 32 and is fastened without slipping out possibility, and then a desired conversion module 1 is completed.

A conversion module 1 composed in this way works as follows after a PGA 2 being mounted on, and then being mounted on a PGA use socket 41 of a motherboard MB more.

A signal of a PGA 2 flowing through a specific socket pin 24A passes through a route of a conductive pattern 16→a input side pad 8a, and is input to a QFP 9. A converted signal that is converted with the QFP 9 passes through a route of an output side pad 8b→a via hole 19→a conductive pattern 15→a via hole 18, and is led to a top surface side land 5Aa of a plated through hole 5A. The converted signal led to the land 5Aa is passes through a route of a copper metal plating layer of a plated through hole 5A→an under surface side land 5A^{b}→an outside connecting pin 6→a pin 43 of a PGA use socket 41, and is supplied to a motherboard MB side. As a result that, in the present embodiment, an exchange connection used a conductor layer C1, C2 of a build-up layer B1 is done in this way, a signal conversion principally by a QFP 9 is attempted, and then a original function of a PGA 2 is shown enough.

Therefore, the following effects can be got according to the present embodiment.

(1) In this conversion module 1, a guidance of a signal line on a sub board and a troublesome soldering work that are necessity for the first invention and the second invention become unnecessary by a reason of forming a build-up layer B1 in a top surface of a conversion board 3. Therefore, a production of this conversion module 1 becomes comparatively simple.

(2) In this conversion module 1, a universal core substrate 17 is used as discussed above. Therefore, it can be coped enough with a changing a position of an exchange connection. That is, for this conversion module 1, it is not necessary to change a specification of a core substrate 17 depending on a position of an exchange connection, and then this conversion module 1 can be contributed for a total cost reduction of a device.

(3) A conversion module 1 of the present embodiment includes a sub board 32 having a pin-penetrating hole 36. Same as the first invention and the second invention, all outside connecting pin Gs are penetrated into pin penetrating hole 36s. So, even if an external force that seems to bend an outside connecting pin 6 adds to one outside connecting pin 6, the external force is dispersed in each pin 36 by the sub board 32. Therefore, a preferred conversion module 1 wherein a pin curve is hard to occur can be realized. And a relative position of an outside connecting pin is not changed, and then an inserting into and extracting from pin 6 does not cause a trouble.

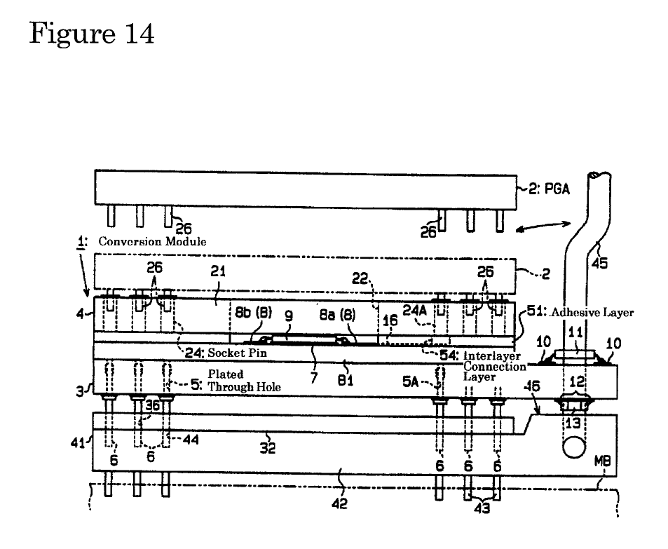

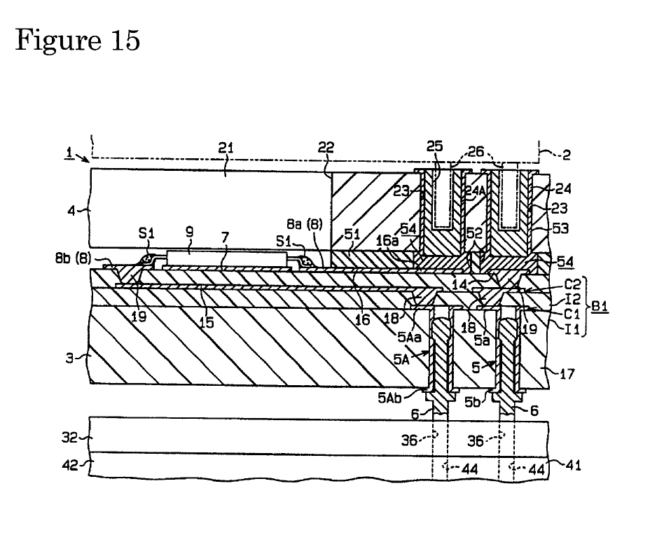

Next, one example of a method to produce a conversion module 1 of the present embodiment comprising a three layer monolithic structure is described based on FIGS. 14-16.

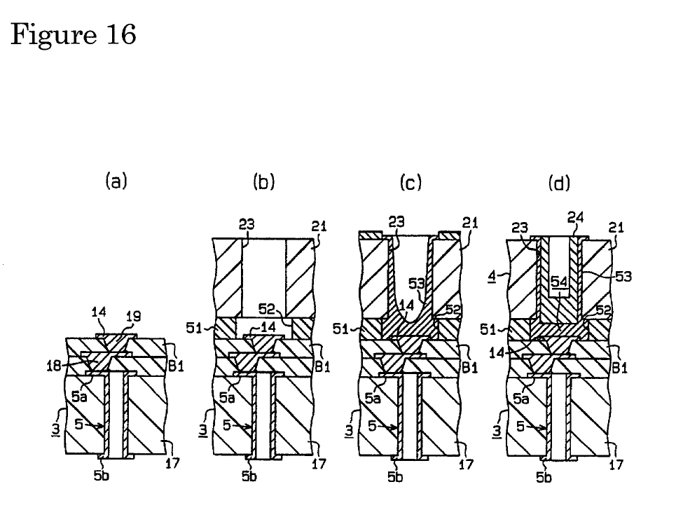

At first, a conversion board 3 is made, and then a build-up layer B1 is formed on an upper plane of the board by a build-up process (cf. FIG. 16(a)).

And, in a surface of the build-up layer B1, an adhesion sheet to become an adhesive layer 51 is disposed. A circle-shaped opening to become a recess 52 is formed at a predetermined point in this adhesion sheet beforehand. Furthermore, on the adhesion sheet, an insulation substrate 21 with a hole to become a socket board 4 later is put. At this time, a pin-holding hole 23 is formed at a predetermined point in the insulation substrate 21 already. And the build-up layer B1 and the insulation substrate 21 are bonded by an adhesive layer 51 unitedly with a pressure force to a depth wise direction of the substrate while heating (cf. FIG. 16(b)).

Next, after a plating resist layer is formed on a top surface of an insulation substrate 21, catalyst addition and activation are done, and then an electro less plating is done more. Still in this process, it is preferable that an under surface side of a core substrate 17 where a copper metal plating does not need to be deposited is covered by such as a plating resist layer that is not illustrated. Then, as shown in FIG. 16(c), an electro less copper plating layer 53 is formed on a primary edge 16a, a surface of a pad 14, an inner wall side of a pin holding hole 23 and an inner wall side of a recess 52. A thick plating by an electro less copper metal plating may be done on a foundation with the electro less copper metal plating layer more in order to ensure a plating thickness. Still, the plating resist layer that became unnecessary is exfoliated now.

Then, each socket pin 24, 24A are held in each pin holding hole 23 by a press-fitting method from a top surface side opening of each pin holding hole 23 (cf. FIG. 16(d)). A socket board 4 is completed at this point then.

After having passed through a substrate adhesion process and a socket pin forming process such as the above, a pin press-fit process is executed subsequently. That is, into each plated through hole 5, 5A of a conversion board 3, an end of an outside connecting pin 6 is pressed and fixed from an under surface side opening. Furthermore, a QFP 9 and an electronic component 11, 13 are soldered to a predetermined point by means of a re-flow in a state of being fixed temporary after printing of solder cream to various pad 7, 8, 8a, 8b, 10, 12. Still, each part may be able to be soldered to the pad individually without printing solder cream.

Then, after an outside connecting pin 6 penetrates into a pin penetrating hole 36 of a sub board 32, and is fastened without slipping out possibility, a desired conversion module 1 is completed.

A conversion module 1 being composed in this way works as following after mounting a PGA 2 and being mounted on a PGA use socket 41 of a motherboard MB more.

A signal of a PGA 2 flowing through a specific socket pin 24A passes through a route of an interlayer connection layer 54→a conductive pattern 16→an input side pad 8a, and is input to a QFP 9. A converted signal being converted here is output from a QFP 9, and passes through a route of an output side pad 8b→a via hole 19→a conductive pattern 15→a via hole 18, and led to a top surface side land 5Aa of a plated through hole 5A. The converted signal led to the land 5Aa passes through a route of a copper metal plating layer in a plated through hole 5A→an under surface side land 5Ab→an outside connecting pin 6→a pin 43 of a PGA use socket 41, and is supplied to a motherboard MB side. As a result that such an exchange connection using a conductor layer C1, C2 of a build-up layer B1 is done, a signal is converted principally by a QFP 9, and then an original function of a PGA 2 becomes show enough.

Therefore, the following effects can be got according to the present embodiment.

(1) In the present embodiment, a connection between a socket pin 24, 24A and a conductor layer C2 becomes surely even though a build-up layer B1 is formed on a conversion board 3.

(2) For a conversion module 1 of the present embodiment, a production method as bellow is picked: after a conversion board 3 is bonded to an insulation substrate 21 having a hole in which a plating layer 53 is formed beforehand, each socket pin 24, 24A is press-fitted into a pin holding hole 23. That is, a production method: a socket board of a commercial product is purchased and is used, as it is not taken. Therefore, materials costs can be held down in comparison with purchasing an expensive commercial product, so that a conversion module of this embodiment can prevent a high cost accounting of a whole.

In addition, an embodiment of the present invention may be changed as follows.

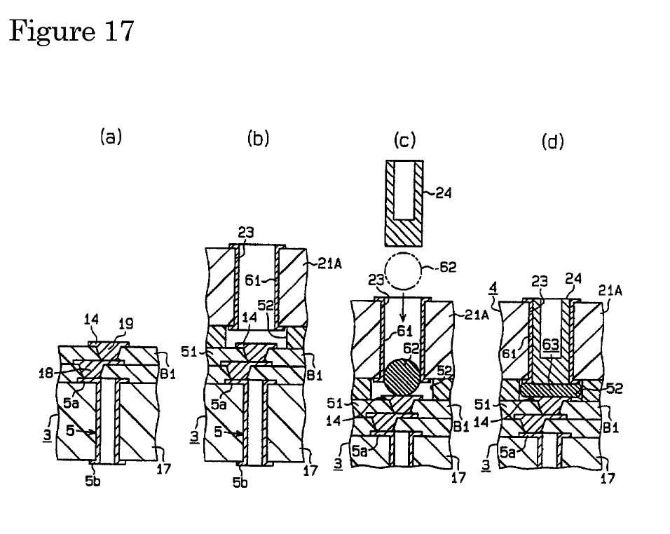

As shown in FIG. 17, after having bonded a build-up layer B1 and an insulation substrate 21 by an adhesive layer 51 unitedly, something like sphere-shaped solder grain 62 that is an electro conductivity metal grain is inserted in each pin holding hole 23, and then each socket pin 24, 24A are inserted into each pin holding hole 23 (cf. FIG. 17(c)). Still, it is preferable that an average particle diameter of the solder grain 62 is a little smaller than an inside diameter of the pin holding hole 23. In addition, the solder grain 62 may not only be inserted by one drop in every hole, but also may be inserted by a plural number grain at need. Next, the solder grain 62 is melted by means of a re-flow furnace, and then is hardened, so that an interlayer connection layer 63 is formed, and then a socket board 4 is completed.

The solder grain can be replaced with solder paste, anisotropy conductive rubber or something. Furthermore, a pin holding hole 23 formed in an insulation substrate 21 can be formed by means of an irradiation of a laser beam to the insulation substrate 21 after having been bonded a build-up layer to the insulation substrate with an adhesive layer.

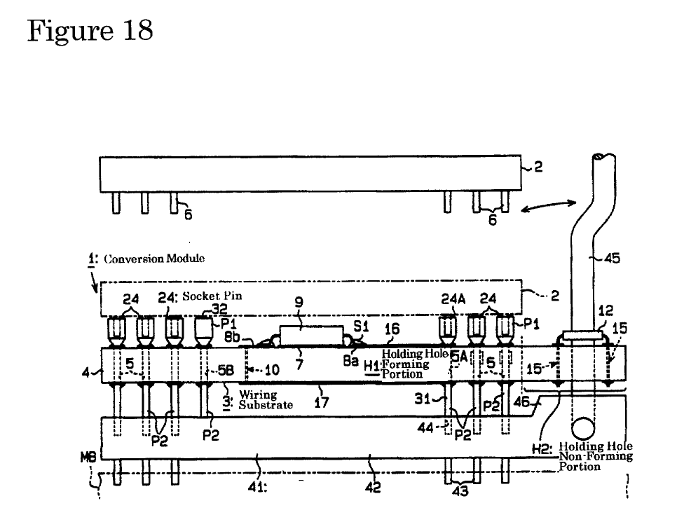

A signal conversion module 1 of one embodiment that is realized the fifth invention is explained based on FIGS. 18-20 as follows.

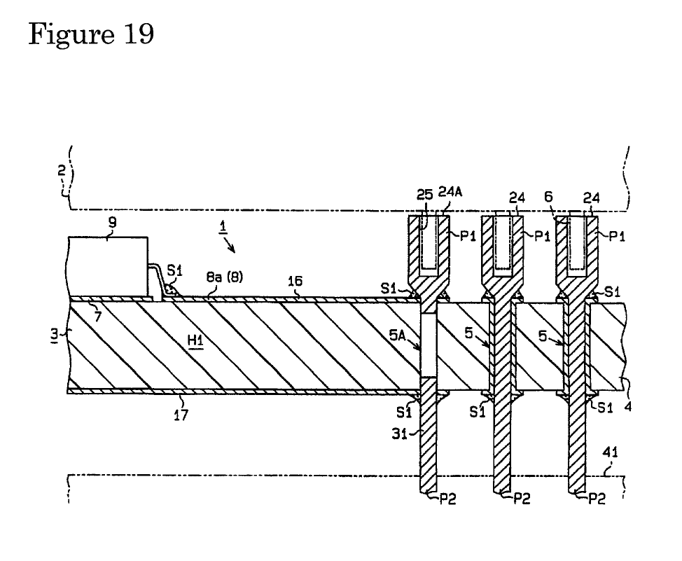

As shown in FIGS. 18 and 19, the signal conversion module 1 of this embodiment is a device that mounts a PGA 2 on a motherboard MB with converting a signal of the PGA 2. In an under surface of the PGA 2, I/O pin 6s as plural terminals is projected regularly.

This conversion module 1 has one-piece structure that consists of only wiring substrate 3 as a conversion board, and conventional so-called a socket board is not had.

A wiring substrate 3 comprises a rigid core substrate 4 of a plane regard rectangle. This core substrate 4 is so-called a double sided board having a conductor layer on both a front side and a backside. In the core substrate 4, a first plated through hole 5 of many (in the present embodiment, several hundred) as a socket pin holding hole are formed. The first plated through hole 5a are arranged in something like a “□” shape observed in a plan, and then constitutes a plated through hole group. A portion wherein the through hole crowds in a core substrate 4 decides to call a holding hole forming portion H1.

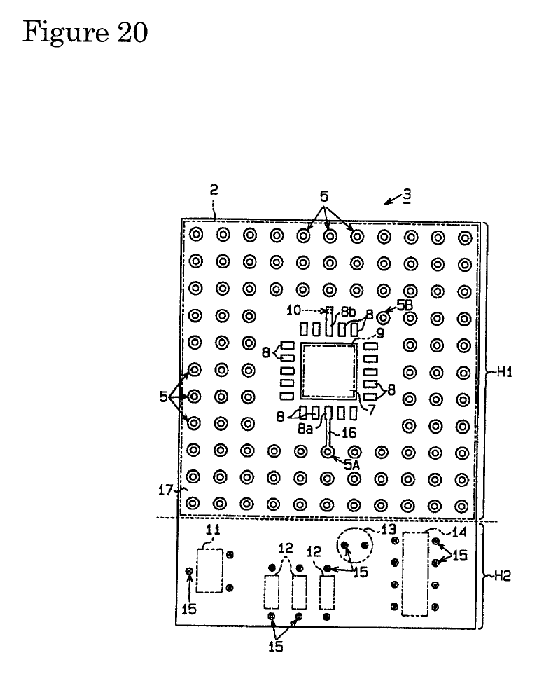

As shown in FIG. 20, a holding hole forming portion H1 of the present embodiment is a something like rectangular area observed in a plan, which is nearly equal to an outside dimension of a PGA 2.

In a top surface of a wiring substrate 3, a die pad 7 of one and a pad 8 of a plural number are formed on a substrate central part surrounded by a plated through hole group. A signal conversion use QFP 9 as a component converting a signal is mounted on a surface of a die pad 7. Each lead of the QFP 9 is joined to each pad 8 with solder S1. One pad among plural pad 8s is assigned as an input side pad 8a for an exchange connection, and another one pad is assigned as an output side pad 8b for the exchange connection. The input side pad 8a is connected to a sec edge of a conductive pattern 16 formed on a top surface of a core substrate 4. The output side pad 8b is connected to an upper end of a mini-via hole 10 of a small diameter opened in the core substrate 4.

As shown in FIGS. 18-20, a core substrate 4 being comprised this wiring substrate 3 has a holding hole non-forming portion H2 in addition to a holding hole forming portion H1. The holding hole non-forming portion H2 is a portion extended from the holding hole forming portion H1 in a substrate horizontal. In the present embodiment, as shown in FIG. 18, the holding hole non-forming portion H2 is a portion extended horizontally in a right side direction from the holding hole forming portion H1, and, is deployed on a truth top of a step part 46 in a socket 41 for a PGA. Here, the holding hole non-forming portion H2 is formed with the holding hole forming portion H1 unitedly; besides, it ensures that several electronic component 11, 12, 13, 14 of a through hole mount technology type can be mounted on there. As a representative example of the through hole mount technology type electronic component 11-14 that should be mounted, there are a resistance, a transistor, a diode, a capacitor, a DIP and so on. These electronic component 1114 comprise plural lead terminals either. And, in each holding hole non-forming portion H2, a second plated through hole 15 where a terminal of each electronic component 11-14 can be inserted into is arranged. Because the second plated through hole 15 is not a hole structure where a socket pin 24 is passed through, it has a diameter smaller than the first plated through hole 5. To the second plated through hole 15, each terminal is inserted from a top surface side opening of a wiring substrate 3, and is soldered. A mutual interval of a pad 8 and a land of a plated through hole 5, 15 is connected electrically by a conductive pattern formed on a top surface side of a wiring substrate 3, which is not illustrated. In an under surface side of the wiring substrate 3, a conductive pattern 17 and so forth are formed similarly. A primary edge of the conductive pattern 17 is connected to a bottom end of a mini-via hole 10. In a predetermined point of the wiring substrate 3, a socket pin holding hole 5A not having a metal plating layer in an inner wall side is comprised differently with the first plated through hole 5. A primary edge of a conductive pattern 16 reaches to an upper end side opening of the socket pin holding hole 5A. On the other hand, a sec edge of a conductive pattern 17 reaches to a bottom end side opening of the socket pin holding hole 5A.

A socket pin 24 used in the present embodiment is a PGA use, and a number of it is around several hundred. The socket pin 24 consists of a head P1 and a leg P2. The socket pin 24 is made from an electro conductivity metallic material. In the head P1 of the socket pin 24, an inserting hole 25 spreading in consonance with the axis direction is formed. This inserting hole 25 has an aperture in a central part of an upper end surface of the head P1, and where an I/O pin 6 of a PGA 2 can be both inserted in and extracted from. That is, each socket pin 24 has a structure that can attach and detach the I/O pin 6 in the head P1. In an inner wall side of the inserting hole 25, convex sections of a conjunction that are not illustrated to hold the I/O pin 6 surely may be formed by facing each other.

About most socket pin 24, a leg P2 of a diameter smaller than a head P1 extends from a central part of a bottom end side of the head P1. A length of the leg P2 is considerably long in comparison with that of the head P1. These socket pin 24s are fixed without slipping out possibility by being soldered in a state of the leg P2 being inserted into a first plated through hole 5. In the above inserted and fixed state of the socket pin 24, a tip of the head P1 protrudes in overall from a top surface of a wiring substrate 3.

About some socket pin (that is, a specific socket pin that needs an exchange connection) 24A is used, so to say, in a state of being divided into a head P1 and a leg P2. A projection in a bottom end side of the head P1 of the specific socket pin 24A is both held by and soldered not to a first plated through hole 5, but to an upper end side opening of a socket pin holding hole 5A where there is not a plating in a through hole wall surface. To a bottom end side opening of the socket pin holding hole 5A, a leg P2 got by means of the division is inserted and soldered. The leg P2 provided by above described division plays as a conduction pin 31 to connect an interval of a wiring substrate 3 and a PGA use socket 41.

In addition, in a plated through hole 5B formed in a wiring substrate 3, a leg P2 of a dummy pin 32 not for participating in an electrical connection but preventing leaning is inserted and fixed by soldering. This dummy pin 32 has a structure same as a socket pin 24 basically. But a leg P2 is formed a little shortish. And, a plated through hole 5B where a dummy pin 32 is fixed to is formed at a position corresponding to a position where there is not a pin insertion hole 44. Therefore, a tip of the dummy pin 32 protruding from an under surface side of a wiring substrate 3 is not inserted in a pin insert and extract hole 44, but is supported by a top surface of a PGA use socket 41.

In a conversion module 1 composed in this way, each I/O pin 6 is penetrated into an inserting hole 25 having an aperture in an upper end surface of a head P1 by a PGA 2 being mounted on a top surface side of a wiring substrate 3. As a result, the PGA 2 side and the wiring substrate 3 side are connected electrically over a socket pin 24, 24A. Such conversion module 1 is mounted on a PGA use socket 41 on a motherboard MB more, and a leg P2 of each socket pin 24 and a conduction pin 31 are penetrated into a pin insert and extract hole 44. Then, the PGA use socket 41 side and the wiring substrate 3 side are connected electrically over the socket pin 24, 24A. On that occasion, a signal of the PGA 2 flowing through a specific socket pin 24A passes through a route of a conductive pattern 16→an input side pad 8a, and is input once to a QFP 9. A converted signal with the QFP 9 passes through a route of an output side pad 8b→a mini-via hole 10→a conductive pattern 17 >a conduction pin 31, and led to a PGA use socket 41. By these structures, a signal is converted by a QFP 9 and other electronic components 11-14, and then an original function of a PGA 2 becomes show enough.

Therefore, the following effects can be got according to the present embodiment.

(1) This conversion module 1 has one-piece structure as discussed above without a socket board. That is, as a result that a socket board becomes needless, a number of sheets of a substrate that should be used decreases, and then this conversion module 1 has a simple structure in comparison with a conventional module.

In addition, an embodiment of the present invention may be changed as follows.

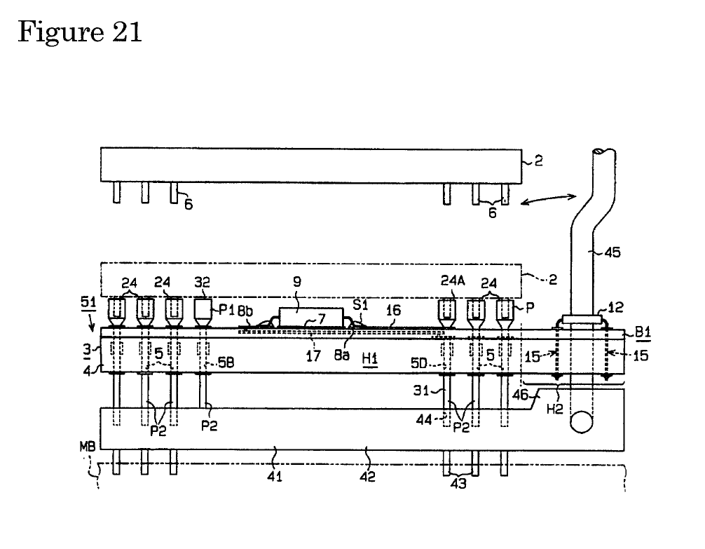

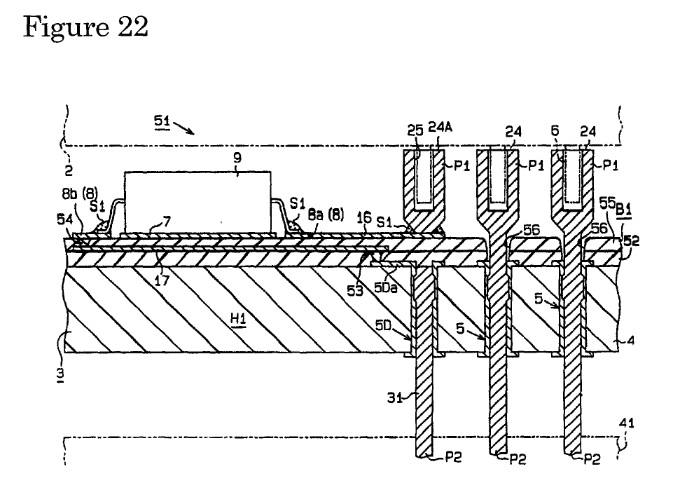

A conversion module 51 that realizes the present invention is explained based on FIGS. 21 and 22. This conversion module 51 differs a structure of a wiring substrate 3 from above-described embodiment. That is, a build-up layer B1 is formed on a top surface side of a core substrate 4 here. A conductive pattern 17 as a first conductor layer is formed on a first insulating layer 52 being comprised the build-up layer B1. In a core substrate 4, a first plated through hole 5D as a socket pin holding hole is formed at a point corresponding to a specific socket pin 24A that needs an exchange connection. A sec edge of a conductive pattern 17 and a top surface side land 5Da of the plated through hole 5D are connected by a via hole 53.

In addition, each pad 7, 8, 8a, 8b or a conductive pattern 16 is formed not on a top surface of a core substrate 4, but on a top surface of a second insulating layer 55 of a build-up layer B1 either. A primary edge of a conductive pattern 17 and a pad 8b are connected by a via hole 54.

In a build-up layer B1, a through-hole 56 where each pin 24, 32 or each terminal can be inserted into is formed on a point corresponding to a plated through hole 5, 5B, 15. But such through-hole 56 is not formed on a point corresponding to a plated through hole 5D.

And a head P1 of a socket pin 24A is soldered to a primary edge of a conductive pattern 16. Therefore, as a result that the head P1 of a specific socket pin 24A connects through a route of a conductive pattern 16→an input side pad 8a→a QFP 9→an output side pad 8b→a via hole 54→a conductive pattern 17→a via hole 53→a land 5Da→a plated through hole 5D, to a conduction pin 31, an exchange connection of a signal line is done.

Therefore, according to the present embodiment, the following effects can be got in addition to the (1) effect in the above-described embodiment.

(2) In this conversion module 51, a signal line can be replaced easily in a top surface side of a wiring substrate 3 by using a conductive pattern 16, 17 of a build-up layer B1 formed on a core substrate 4. That is, this conversion module 51 has a structure suited for an exchange connection, and is profitable, for example, to a case of a plural signal lines that should be replaced.

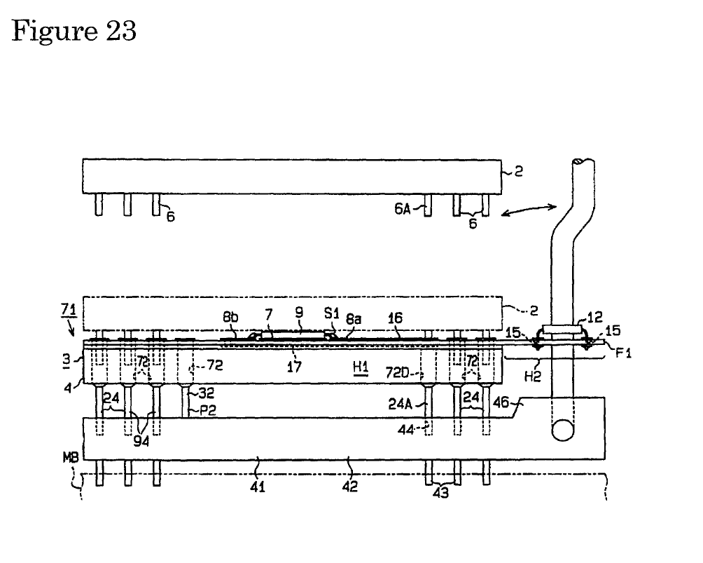

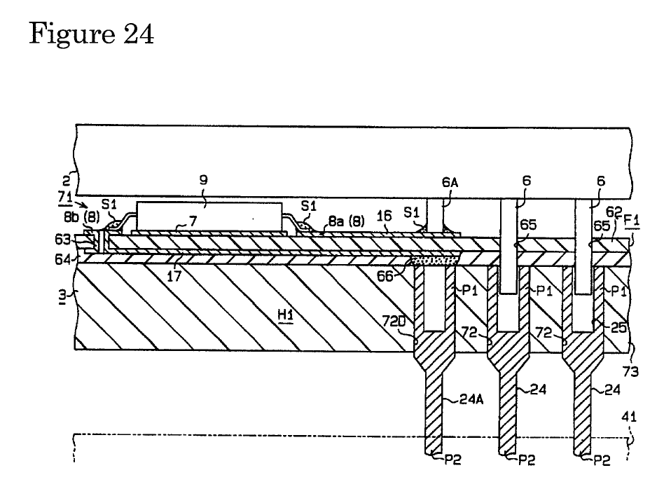

Next, a conversion module 71 according to the present invention is explained based on FIGS. 23 and 24.

A wiring substrate 3 of this conversion module 71 has a structure of two layers being affixed each other. In this wiring substrate 3, so-called a socket board 73 is selected instead of a rigid core substrate 4, and a flexible substrate F 1 is bonded to a top surface side of the socket board 73. The socket board 73 is formed by molding a head P1 of a socket pin 24, 24A, 32 in a resin material. A leg P2 of each socket pin 24, 24A protrudes from an under surface side opening of a socket pin holding hole 72, 72D toward the lower part. As a socket board 73, a general commercial product may be used.

Most I/O pin 6 of a PGA 2 is penetrated through a through-hole 65 of a flexible substrate F1, and furthermore, is penetrated into an inserting hole 25 of a socket pin 24. A specific I/O pin 6A that needs an exchange connection in a PGA 2 are used after being cut in order to shorten in comparison with other I/O pin 6. This I/O pin 6A is not penetrated into an inserting hole 25, but is soldered to a primary edge of a conductive pattern 16. And, a solder precoat layer 66 connects a sec edge of a conductive pattern 17 and an upper end surface of a socket pin 24A electrically. As a result, an exchange connection of a signal line, which uses a conductive pattern 16 of a flexible substrate F1, 17 comes true.

Therefore, the above described effect of (1) and (2) can be got according to the present embodiment.

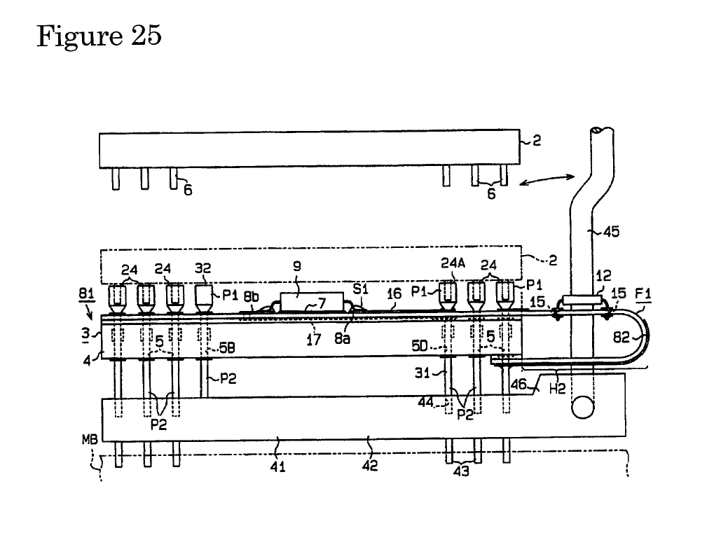

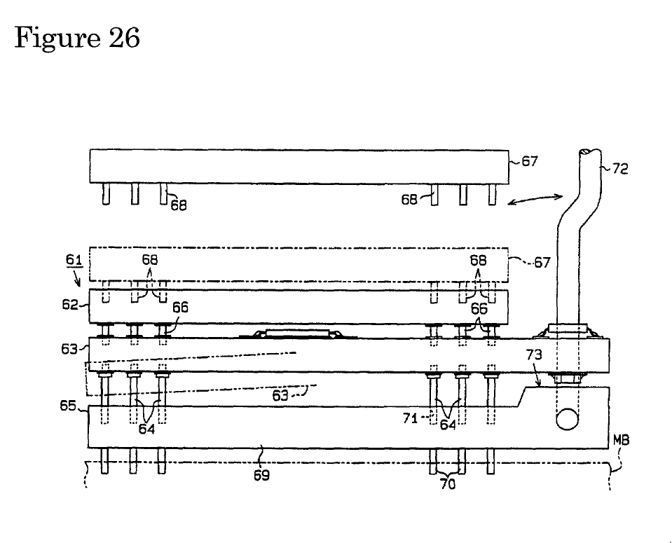

Furthermore, the present invention may be composed like a conversion module 81 shown in FIG. 25. Here, a projecting portion in a flexible substrate F1 is made longer, and an end is bent for 180 degrees in an opposite direction. A bent end of the flexible substrate F1 is fixed by a leg P2 of a socket pin 24 being inserted at an under surface side of a core substrate 4. As a result of this constitution, a top surface side and an under surface side of a wiring substrate 3 can be connected electrically by using a conductive pattern 82 of the flexible substrate F1, and then a degree of freedom of a pattern design improves.

If this technology is used, by only making a conductor circuit being formed only in a top surface side with a flexible substrate, a structure to connect an output side pad 8b to a conduction pin 31 over only the conductor circuit that passes a part being bent, and turns around on a back side of a wiring substrate is realized, and then a through hole 63 and a conductor circuit 17 in FIG. 24 become needless.

In addition, a socket pin 24, 24A is not limited for a PGA use of each embodiment, and it may be a structure of such as a BGA (Ball Grid Array) use.

Furthermore, as a dummy pin, it is possible to use a pin having a different structure from a socket pin 24, 24Aa, concretely, a simple pin that does not have a mechanism that can attach and detach a terminal, of course.

In addition, instead of using above described dummy pin 32, by arranging a leaning preventing substrate on an under surface side of a wiring substrate 3a, a degree of leaning of the whole module may be prevented.

Of course, a shape and an area of a holding hole non-forming portion H2 such as a projecting portion in a flexible substrate F1 can be changed optionally. In addition, such a projecting portion is not formed only in one place in a wiring substrate 3, but also may be formed in a plural number places on a wiring substrate 3.

A holding hole non-forming portion H2 such as a projecting portion in a flexible substrate F1 may be used for an object aside from an object of mounting an electronic component 11-14 for a through hole mount technology. For example, an electronic component for a surface mount technology may be mounted on along with an electronic component 11-14 for a through hole mount technology. In other words, a surface mount use pad may be formed on a holding hole non-forming portion H2 in conformity to a plated through hole 15.

A holding hole non-forming portion H2 can be extended from a holding hole forming portion H1 by bonding a rigid substrate instead of a flexible substrate F1.

A substrate that is formed a conductive pattern and a pad both of a predetermined shape directly on a surface of a socket board 73 that is a commercial product may be used as a wiring substrate 3. As a pattern forming method of that case, there is the printing method, for example.

Obviously, numerous modifications and variations of the present invention are possible in light of the above teachings. It is therefore to be understood that within the scope of the appended claims, the invention may be practiced otherwise than as specifically described herein.

What is claimed as new and desired to be secured by Letters Patent of the United States is:

1. An electronic part module which is configured to electrically connect an electronic component to a motherboard via a socket, comprising:
a conversion board configured to convert a signal from the electronic component and having a plurality of pins projected from the conversion board, the plurality of pins being configured to contact the socket; and
a sub board provided between the conversion board and the socket and having a plurality of holes each having a diameter same as or larger than that of each of the plurality of pins which pass through the plurality of holes, respectively.

2. An electronic part module which is configured to electrically connect an electronic component to a motherboard via a socket, comprising:
a socket board having a plurality of socket pins to which terminals of the electronic component are configured to be detachably connected; and
a conversion board configured to convert a signal from the electronic component and having a plurality of pin insertion holes, the socket pins passing through the pin insertion holes to contact the socket.

3. An electronic part module which is configured to electrically connect an electronic component to a motherboard via a socket, comprising:
a conversion board configured to convert a signal from the electronic component and having a build-up layer formed on a surface of the conversion board, a signal line necessary to convert the signal from the electronic component being provided on the build-up layer.

4. An electronic part module according to claim 3, further
comprising:
a rigid core substrate having a plurality of socket pin structures to which terminals of the electronic component are configured to be detachably connected; and
a bonding structure configured to bond the rigid core substrate to a surface of the build-up layer and having an interlayer connection structure which connects the plurality of socket pin structures and a wiring provided on the build-up layer.

5. An electronic part module which is configured to electrically connect an electronic component to a motherboard via a socket, comprising:
a conversion board configured to convert a signal from the electronic component and having a plurality of socket pin structures to which terminals of the electronic component are configured to be detachably connected.
